(19) United States
(12) Patent Application Publication
(10) Pub. No.: US 2025/0333878 A1
(43) Pub. Date: Oct. 30, 2025

(54) METHOD FOR PRODUCING SILICON SINGLE CRYSTAL

(71) Applicant: Shin-Etsu Handotai Co., Ltd., Tokyo (JP)

(72) Inventor: Keisuke MIHARA, Nishigo-mura (JP)

(73) Assignee: Shin-Etsu Handotai Co., Ltd., Tokyo (JP)

(21) Appl. No.: 18/870,058

(22) PCT Filed: May 26, 2023
(86) PCT No.: PCT/JP2023/019599

§ 371 Date: Nov. 27, 2024

(30) Foreign Application Priority Data
Jun. 17, 2022 (JP) 2022-098299

(51) Int. Cl. C30B 30/04; C30B 15/30; C30B 29/06

(52) U.S. Cl. CPC C30B 30/04; C30B 15/30; C30B 29/06

(57) ABSTRACT

A method for producing silicon single crystal by CZ method using a cusp magnetic field formed by upper and lower coils coil provided in pulling furnace, the silicon single crystal is pulled up in a straight-body step by setting a rotational rate of the silicon single crystal to 7 rpm or more and 12 rpm or less, rotational rate of a quartz crucible to 1.0 rpm or less, position of a magnetic field minimum plane of the cusp magnetic field in a range of 10 mm downward to 5 mm upward from a raw-material melt surface, and intensity of magnetic field of cusp magnetic field at intersection of plane having same height as magnetic field minimum plane and inner wall of quartz crucible from 800 to 1200 G. Method for efficiently producing silicon single crystal having lower oxygen concentration and better in-plane distribution of oxygen concentration compared to conventional techniques.

### TECHNICAL FIELD

The present invention relates to a method for producing a silicon single crystal by a CZ method using a cusp magnetic field formed by an upper coil and a lower coil provided in a pulling furnace.

### BACKGROUND ART

In recent years, power devices have been attracting attention as devices to realize power saving. A region where an electric current flows in the power device may be in the thickness range of approximately tens or hundreds of micrometers from a surface layer, or in some cases, the electric current flows an entire wafer. When an oxygen precipitate or a BMD (Bulk Micro Defect) exists in the region where this electric current flows, breakdown voltage failure or leakage failure may occur.

To prevent the above failures, silicon single crystal wafers for power devices are required to have a low oxygen concentration to the extent that oxygen precipitate is not generated and flat in-plane distribution of the oxygen concentration. In addition, in RF (high frequency) devices used for communication such as smartphones, silicon single crystal wafers for RF devices are also required to have the low oxygen concentration and flat in-plane distribution of the oxygen concentration because the existence of an oxygen donor degrades high-frequency characteristics of the devices.

One of typical production methods for silicon single crystals for the power devices or the RF devices is a Czochralski (Czochralski: CZ) method. When producing the silicon single crystals by using the CZ method, a mainstream thereof is to use a magnetic field applied CZ (MCZ) method in which a magnetic field is applied to a raw-material melt and single crystals are pulled up. As methods for growing low-oxygen crystals for the power devices, a method using a horizontal magnetic field and a method using a cusp magnetic field are known.

As the method using the horizontal magnetic field, for example, Patent Document 1 discloses a method to obtain a low-oxygen crystal by specifying a crystal rotational rate and a crucible rotational rate under the horizontal magnetic field, while Patent Document 2 discloses a method to set an intensity of a magnetic field to 2000 G or more, a rotational rate of a quartz crucible to 0.2 rpm or less, a crystal rotational rate to 5 rpm or less.

On the other hand, as a method using the cusp magnetic field, for example, Patent Document 3 discloses a method to move a magnetic field central position (position of magnetic field minimum plane) of the cusp magnetic field depending on a decreased amount of silicon melt to a position where a temperature of the melt is stabilized.

Moreover, Patent Document 4 discloses a method to set a magnetic field central position (position of magnetic field minimum plane) upward from 10 to 100 mm from a melt surface and make a crystal rotational rate of 15 to 20 rpm, while Patent Document 5 discloses a method in which a distance between a bottom edge of a heat shielding material and a melt surface is set to 50 to 120 mm, a magnetic field central position is set between the melt surface and a half of a melt depth, and a crystal rotational rate is set to 13 rpm or more.

Patent Document 6 discloses a method in which an intensity of a magnetic field of a cusp magnetic field is 0.05 T to 0.12 T, a magnetic field central position relative to a melt surface is 0 mm to −30 mm (30 mm downward), a crystal rotational rate is 8 to 14 rpm, and a crucible rotational rate is 1.3 to 2.2 rpm.

### CITATION LIST

### Patent Literature

Patent Document 1: JP 2009-18984 A

Patent Document 2: WO 2009/025340 A1

Patent Document 3: JP 2001-89289 A

Patent Document 4: JP 2020-33200 A

Patent Document 5: JP 3783495 B2

Patent Document 6: JP 2019-31436 A

### SUMMARY OF INVENTION

### Technical Problem

In methods disclosed in Patent Documents 1 and 2, a crystal rotational rate is set to about 5 rpm (Patent Document 1) or equal to or lower (Patent Document 2); however, a problem arises when the crystal rotational rate is set to a low rate, resistivity and in-plane distribution of oxygen deteriorate, which results in a factor leading to device failures.

In a method disclosed in Patent Document 3, along with a rise in a solidification ratio of a single crystal, a position of the magnetic field minimum plane of a cusp magnetic field is elevated. A change in the position of the magnetic field minimum plane within a product portion causes an increase in an amount of change in oxygen concentration in the product portion, resulting in a problem in which yield is significantly reduced when a crystal with a narrow specification range of an oxygen concentration or a low-oxygen crystal is produced.

When producing a small-diameter single crystal having a diameter of 200 mm or less, a crystal rotational rate disclosed in Patent Documents 4 and 5 causes no problem, but when producing a large-diameter single crystal having a diameter of 300 mm or more, the crystal rotational rate which is increased to 13 rpm or more causes a problem in which a diameter fluctuation during a pulling up of the single crystal is increased thereby continuation of an operation is impossible.

An oxygen concentration disclosed in Patent Document 6 is a result of a model prediction based on a numerical analysis, the oxygen concentration is only at one point near the center. In the production of a large-diameter single crystal having a diameter of 300mm or more, when the rotational rate of a quartz crucible is increased to 1.3 rpm or higher as disclosed in Patent Document 6, a problem arises in which a value of the oxygen concentration is increased and in-plane distribution of the oxygen concentration deteriorates.

The present invention has been made in view of the above-described problem. An object of the present invention is to provide a method for efficiently producing a silicon single crystal having a lower oxygen concentration and better in-plane distribution of the oxygen concentration than conventional techniques.

### Solution to Problem

To achieve the above object, the present invention provides a method for producing a silicon single crystal by a CZ method using a cusp magnetic field formed by an upper coil and a lower coil provided in a pulling furnace, wherein
the silicon single crystal is pulled up in a straight-body step by setting a rotational rate of the silicon single crystal to 7 rpm or more and 12 rpm or less, a rotational rate of a quartz crucible to 1.0 rpm or less, a position of a magnetic field minimum plane of the cusp magnetic field in a range of 10 mm downward to 5 mm upward from a raw-material melt surface, and an intensity of the magnetic field of the cusp magnetic field at an intersection of a plane having a same height as the magnetic field minimum plane and an inner wall of the quartz crucible from 800 to 1200 G.

According to such a method for producing a silicon single crystal, problems such as an increase in oxygen concentration and deterioration of in-plane distribution of the oxygen concentration when a crucible rotation rate is high are eliminated, and thus efficient production of the single crystal is enabled in which a low oxygen concentration and the excellent in-plane distribution of the oxygen concentration satisfy a required quality for a power device and an RF device.

In this case, the method for producing a silicon single crystal can produce the silicon single crystal in which an oxygen concentration based on ASTM' 79 is 2×10¹⁷ atoms/cm³ or less, and an ROG in a crystal cross-section at right angles to a growth direction of the silicon single crystal is 8% or less.

The inventive method for producing a silicon single crystal can stably produce such a silicon single crystal having high quality.

### Advantageous Effects of Invention

As described above, according to the inventive method for producing a silicon single crystal, problems such as an increase in an oxygen concentration and deterioration of an in-plane distribution of the oxygen concentration when a crucible rotation rate is high are eliminated, and thus efficient production of the single crystal is enabled in which a low oxygen concentration and the excellent in-plane distribution of the oxygen concentration satisfy a required quality for a power device and an RF device.

### BRIEF DESCRIPTION OF DRAWINGS

FIG. 1 is a view describing an example of a single-crystal-producing apparatus.

FIG. 2 shows an in-plane distribution of an oxygen concentration obtained from straight bodies at 100 cm in Examples 1 and 2.

FIG. 3 shows dependency of an oxygen concentration in a single crystal on a crucible rotation rate.

FIG. 4 shows in-plane distribution of oxygen concentration obtained from a straight body at 100 cm in Comparative Example 2.

### DESCRIPTION OF EMBODIMENTS

Hereinafter, the present invention will be described in detail. However, the present invention is not limited thereto.

As described above, a method for producing a silicon single crystal, which efficiently produces a single crystal having lower oxygen concentration and better in-plane distribution of the oxygen concentration than a conventional technique has been desired.

To solve the above problem, the present inventor has earnestly studied a method for producing a silicon single crystal by a CZ method using a cusp magnetic field formed by an upper coil and a lower coil provided in a pulling furnace, in which the silicon single crystal is pulled up in a straight-body step by setting a rotational rate of the silicon single crystal to 7 rpm or more and 12 rpm or less, a rotational rate of a quartz crucible to 1.0 rpm or less, a position of a magnetic field minimum plane of the cusp magnetic field in a range of 10 mm downward to 5 mm upward from a raw-material melt surface, and an intensity of the magnetic field of the cusp magnetic field at an intersection of a plane having a same height as the magnetic field minimum plane and an inner wall of the quartz crucible from 800 to 1200 G. As a result, it has been found out that problems such as increase of the oxygen concentration or deterioration of the in-plane distribution of the oxygen concentration when a crucible rotational rate is high are eliminated, thus enabling efficient production of the single crystal having a low oxygen concentration and an excellent in-plane distribution which satisfy required quality for a power device or an RF device. This finding has led to the completion of the present invention.

As described above, in recent years, a higher quality level of the low-oxygen crystal for the power device or the RF device than a conventional level is required. In particular, with regard to the oxygen concentration, it is desired to be 2×10¹⁷ atoms/cm³ or less (ASTM' 79) to eliminate the effect of thermal donor generated during low-temperature heat treatment. In addition, it is desirable to make the in-plane distribution of the oxygen concentration uniform to eliminate quality variations between chips. For example, when the oxygen concentration is low on the periphery of a wafer, a slip dislocation may be generated on the periphery during heat treatment and then adversely affects to yield of a device process in some cases.

As a countermeasure to this case, it is important to make the oxygen concentration uniform in the plane. Hereinafter, ROG (Radial Oxygen Gradient: oxygen concentration gradient) is used as an indicator to measure the quality of the in-plane distribution of the oxygen concentration. ROG is defined as values obtained by measuring the oxygen concentration at least at two positions, one of which is the center of the wafer and the other is a predetermined position from the periphery of the wafer, and the values are calculated by the following formula,

$$( Maximum value - Minimum value ) \times 100 / Maximum value )$$

In recent years, ROG has also been required to have a higher level than the conventional level and excellent distribution that satisfies ROG being smaller than 8% has been required.

Incidentally, in a CZ method, the single crystal is grown by rotating while pulling up. When pulling up a large diameter single crystal having a diameter of 300 mm or more by a CZ method using a cusp magnetic field, a crystal rotational rate of an extremely high rate increases a variation of a crystal diameter during pulling up of the single crystal and causes a problem to prevent continuing operation. Conversely, when the crystal rotational rate is set to an extremely low rate, resistivity and the in-plane distribution of the oxygen concentration are degraded, which causes a problem to be a factor for device failure. To avoid these problems, in the CZ method using the cusp magnetic field, it is necessary to avoid a condition where the crystal rotational rate is extremely high or a condition where the rate is extremely low.

Moreover, in the MCZ method, silicon melt (hereinafter, also referred to as “raw-material melt”) is accommodated in the quartz crucible, but oxygen is incorporated into the silicon melt by elution of oxygen from the quartz crucible during a crystal pulling, thereby increasing the oxygen concentration in the single crystal. When a silicon melt surface (surface) is viewed down from the vertical direction in the MCZ method using the horizontal magnetic field, convection is suppressed in the direction parallel to the magnetic field lines because the magnetic field affects this direction. Still, convection is activated in the direction vertical to the magnetic field lines because almost no magnetic field affects this direction. Thus, the region where the convection is locally active is formed, and the oxygen becomes easier to elute from the quartz crucible in the horizontal magnetic field, as a result, enriching a high oxygen concentration of the single crystal.

On the other hand, in the case of the cusp magnetic field, the magnetic field affects a vicinity of an inner wall of the quartz crucible (hereinafter, may be simply referred to as “wall of crucible” or “inner wall of crucible”) in an entire circumference; thus, convection in the vicinity of the wall of the crucible is suppressed in the entire circumference. Consequently, in the cusp magnetic field, when a rotational rate of the crucible is sufficiently fast, and an intensity of the magnetic field turns into a high magnetic field, then the relative velocity between the quartz crucible and the silicon melt becomes high. Then, the elution of the oxygen is facilitated. On the contrary, when the rotational rate of the crucible is sufficiently low, and the intensity of the magnetic field turns into a low magnetic field, then the relative velocity between the quartz crucible and the silicon melt becomes slow. Then, the elution of oxygen is suppressed.

In addition to the described above, by defining the position of the magnetic field minimum plane in the cusp magnetic field close to a condition of a solid-liquid interface of the single crystal and the silicon melt, or a position above, natural convection inherent to the cusp magnetic field facilitates the incorporation of the oxygen into the single crystal side from a layer of the low oxygen concentration on the silicon melt surface. Therefore, it is possible to realize the low oxygenation of the crystal only after using the cusp magnetic field, sufficiently slowing the crucible rotational rate, making the intensity of the magnetic field turn into a low magnetic field, and defining the position of the magnetic field minimum plane to a position close to the solid-liquid interface of the single crystal and the silicon melt, or the position above.

The present invention is a method for producing a silicon single crystal by a CZ method using a cusp magnetic field, in a straight-body step, setting a rotational rate of the silicon single crystal to 7 rpm or more and 12 rpm or less, a position of a magnetic field minimum plane of the cusp magnetic field in a range of 10 mm downward to 5 mm upward from a raw-material melt surface, a rotational rate of a quartz crucible to 1.0 rpm or less, and an intensity of the magnetic field of the cusp magnetic field (hereinafter, may be simply referred to as “intensity of magnetic field”) at an intersection of a plane having a same height as the magnetic field minimum plane and an inner wall of the quartz crucible from 800 to 1200 G.

Hereinafter, an example of a single-crystal producing apparatus suitably used for the inventive method for producing a silicon single crystal is described with reference to the drawings. Note that the description of the same portion with a conventional apparatus may be omitted as appropriate.

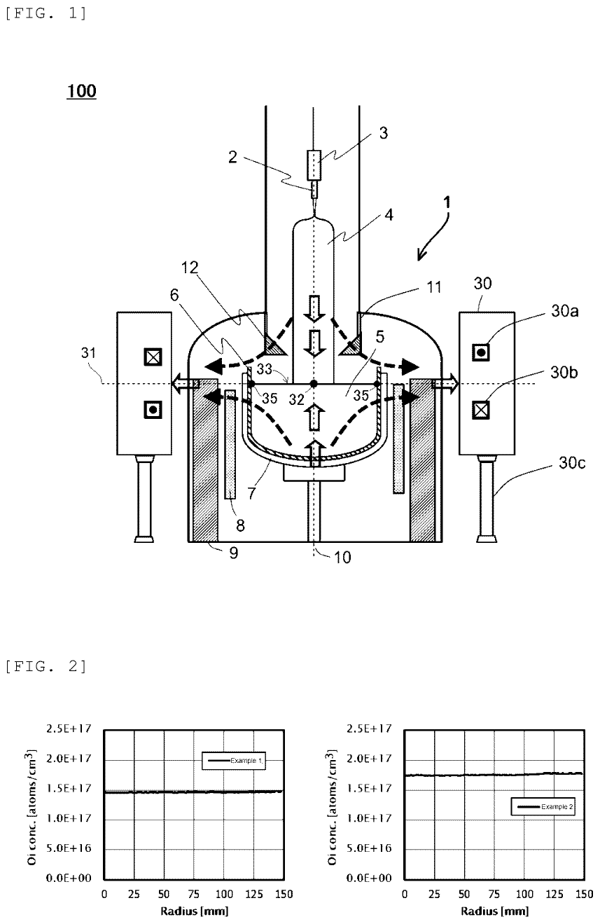

FIG. 1 shows an example of the single-crystal producing apparatus (single-crystal pulling apparatus). A single-crystal producing apparatus (single-crystal pulling apparatus) 100 shown in FIG. 1 is configured to have a heat-insulating material 9, a heater 8 inside of the heat-insulating material 9, and a heat shielding member 12 facing a silicon raw material melt 5 accommodated in a quartz crucible 6 installed in a graphite crucible 7 at a lower end of a cylindrical part 11. The apparatus is configured to have a pulling furnace 1 provided with a central axis 10, and a magnetic field generator 30 having an upper coil 30a and a lower coil 30b installed in the surrounding area of the pulling furnace 1, in which the cusp magnetic field is applied to the silicon melt by energizing the upper coil 30a and the lower coil 30b, and the single crystal is pulled up to the central axis direction. Moreover, a seed crystal 2 held by a seed holder 3 connected to a wire on the central axis 10 of the pulling furnace 1 is brought in contact with the silicon melt 5, thereby performing seeding. Then, the diameter of the silicon single crystal is enlarged. Then, a silicon single crystal 4 is produced by configuration to pull a straight body portion to be a product portion toward a pulling direction.

The magnetic field generator 30 is installed on an elevating device 30c, which is movable up and down to the vertical direction and provided with the upper coil 30a and lower coil 30b to surround the side of the pulling furnace 1. In the cusp magnetic field, magnetic field lines that repel each other vertically are generated by applying electric currents in opposite directions to two upper and lower coils. At this time, due to an effect of a magnetic field distribution formed by each of the upper coil 30a and the lower coil 30b, a region (magnetic field minimum plane 32) is formed between the upper coil 30a and the lower coil 30b, where the intensity of the magnetic field is minimized near the central axis 10. For example, when the electric current values of the upper coil 30a and the lower coil 30b are the same value and the electric current passes in opposite directions, the magnetic field distribution is vertically symmetrical and horizontally symmetrical. In this case, the intensity of the magnetic field at an intersection of the central axis 10 and the magnetic field minimum plane 32 is the weakest. Note that FIG. 1 shows a case where the height position of the magnetic field minimum plane 32 (i.e., the height position of a plane 31 at the same height as the magnetic field minimum plane) is the same as the height position of a raw material melt surface 33. Note that arrows in black dashed lines in FIG. 1 indicate the actual magnetic field distribution and white arrows on the central axis indicate that the vertical direction component of the magnetic field is dominant, while white arrows on the midline between the two coils indicate the horizontal direction component of the magnetic field is dominant.

Moreover, by setting the electric current values of the upper coil 30a and the lower coil 30b differently from each other, and applying electric currents in opposite directions to the two upper and lower coils to perform unbalanced excitation, the magnetic field distribution becomes asymmetrical from the top to bottom and symmetrical from left to right (hereinafter, referred to as “unbalanced excitation”) and the position of the magnetic field minimum plane 32 is moved compared to when the electric current values of the upper and lower coils are set to the same value. For example,

Electric current value of the upper coil>Electric current value of the lower coil,
this indicates that the position 32 of the magnetic field minimum plane shifts to a lower side compared to the case where the electric current values of the upper and the lower coils are defined to the same value, and when
Electric current value of the upper coil<Electric current value of the lower coil,
this indicates that the position 32 of the magnetic field minimum plane shifts to an upper side compared to the case where the electric current values of the upper and lower coils are defined to the same value.

In the present invention, the position of the magnetic field minimum plane 32 is set in a range of 10 mm downward to 5 mm upward from the raw-material melt surface 33 during the product portion (straight-body step), but it is necessary to move the position of magnetic field minimum plane before pulling the product portion (straight-body step). As for the method for moving the magnetic field minimum plane at this time, the position of the magnetic field minimum plane may be moved by moving the magnetic field generator 30 up and down using the elevating device 30c. Alternatively, the position of the magnetic field minimum plane may be moved by performing the unbalanced excitation with the different current values for the upper coil 30a and lower coil 30b.

Moreover, as described earlier, the strength of the convection suppression force near the inner wall of the quartz crucible is determined by the intensity of the magnetic field near the inner wall of the quartz crucible. Consequently, in the MCZ method using the cusp magnetic field, the intensity of the magnetic field near the inner wall of the quartz crucible becomes an important factor in determining the oxygen concentration. Therefore, the intensity of the magnetic field in the present invention is determined to have a value of 800 to 1200 G as a value at the intersection 35 of the plane 31 having the same height as the magnetic field minimum plane and the inner wall of the quartz crucible. Note that it can be restated that the plane 31 having the same height as the magnetic field minimum plane is a plane including the magnetic field minimum plane 32 and the intersection 35 is a point at a position having the same height position of the magnetic field minimum plane 32 on the inner wall of the quartz crucible.

In addition, a structure of HZ (hot zone) other than the above can be the same structure as that of a typical single-crystal-producing apparatus for CZ silicon. However, it is an essential condition that the rotational rate of the quartz crucible can be set to 1.0 rpm or less.

In the CZ method, the single crystal is grown while the single crystal is rotated; however, in order to obtain the single crystal having the low oxygen concentration and the excellent in-plane distribution of the oxygen concentration without degrading production performance, in the present invention, the crystal rotational rate of the single crystal is set to 7 rpm or more and 12 rpm less in the step of straight body.

Moreover, in the CZ method, the single crystal is grown while the quartz crucible is rotated. However, the magnetic field acts in the entire vicinity of the crucible wall in the cusp magnetic field, thereby suppressing convection in the entire vicinity of the crucible wall. Consequently, when the rotational rate of the quartz crucible is too high in the cusp magnetic field, a relative rate between the quartz crucible and the raw-material melt becomes high, causing a problem in which the elution of the oxygen is facilitated and the oxygen concentration in the single crystal is increased.

In addition to the above problem, particularly in a large-diameter single crystal, for example, in the production of a single crystal having a diameter of 300 mm or more, when the rotational rate of the quartz crucible is too high, a problem arises where the in-plane distribution of the oxygen concentration deteriorates. To solve these problems, in the present invention, the rotational rate of the quartz crucible is set to 1.0 rpm or less. The lower limit of rotational rate of the quartz crucible is not particularly limited but can be 0.1 rpm or more.

In this way, in the strait body step, by setting the crystal rotational rate of the single crystal to 7 rpm or more and 12 rpm or less, the position of the magnetic field minimum plane of the magnetic field in a range of 10 mm downward to 5 mm upward from a raw-material melt surface, the rotational rate or the quartz crucible to 1.0 rpm or less, the intensity of the magnetic field of the cusp magnetic field from 800 to 1200 G; the excellent in-plane distribution of oxygen concentration can be obtained while the low oxygen concentration of 2×10¹⁷ atoms/cm³ (ASTM' 79) or less is maintained. Note that the lower limit of the oxygen concentration is not particularly limited, but for example, 5×10¹⁵ atoms/cm³ or more (ASTM' 79). The lower limit of the in-plane distribution (ROG) of the oxygen concentration is not particularly limited, either, but for example, 0% or more.

### EXAMPLE

Hereinafter, the present invention will be specifically described with reference to Examples. However, the present invention is not limited thereto.

A 32-inch (approximately 800 mm) crucible in a CZ pulling machine was used to melt 360 kg of raw material and then a single crystal with a diameter of 300 mm was pulled up applying a cusp magnetic field. In these Examples and Comparative Examples, vertically symmetrical excitation with equal current values in an upper and lower coils of the cusp magnetic field, and unbalanced excitation with different current values in the upper and lower coils were performed. Note that when performing the unbalanced excitation in the product portion, a magnetic field position was set using an elevating device to make a position of magnetic field minimum plane 70 mm downward from a raw-material melt surface in advance, then a degree of imbalance was set to a predetermined value at an non product portion and transited to the product portion. At this time the degree of imbalance between the upper and lower coils was determined by a value of the following formula,

$$Degree of imbalance = Electric current value of the lower coil / Electric current value of the upper coil .$$

Samples were cut out from the single crystal after pulling at lengths of 20 cm, 50 cm, 75 cm, and 100 cm of the straight and inspected in-plane distribution of oxygen concentration using FT-IR. Values of the oxygen concentration shown below indicated values at the center of wafers.

Moreover, ROG was defined as a value obtained by measuring the oxygen concentration at two points, the center of the wafer and position 2 mm from an outer edge of the wafer, and by using the following formula,

$$( Maximum value - Minimum value ) \times 100 / Maximum value$$

In addition, ROGs in Tables are defined as average values between 20 cm to 100 cm of the straight body positions.

### Examples 1 and 2

Silicon single crystals were produced under the conditions shown below in Examples 1 and 2.

### [Straight Body Step (Product Portion)]

Position of a magnetic field minimum plane: 10 mm downward from a melt surface
Degree of imbalance between upper and lower coils: 1.00 (Vertically symmetrical excitation)
Intensity of the magnetic field at an intersection of a plane having a same height as a magnetic field minimum plane and an inner wall of a crucible: 1000 G
Rotational rate of the crucible: 0.5 rpm (Example 1), 1.0 rpm (Example 2)
Rotational rate of the single crystal: 10 rpm

In Examples 1 and 2, production of a total of two single crystals was performed, fixing a position of a magnetic field minimum plane of a cusp magnetic field, a degree of imbalance between upper and lower coils, an intensity of the magnetic field, and a rotational rate of the single crystal in a straight body step, while setting rotational rates of a crucible to 0.5 rpm (Example 1) and 1.00 rpm (Example 2). Table 1 shows the conditions and results of Examples 1 and 2, FIG. 2 shows an in-plane distribution of the oxygen concentration obtained at 100 cm of a straight body of Examples 1 and 2.

TABLE 1

| | Product | Degree of | | | | | | |
|---|---|---|---|---|---|---|---|---|
| | Portion: | Imbalance | Intensity | Rotational | Rotational | | | |
| | Position of | between | of | Rate | Rate | | | |
| | Magnetic Field | Upper and | Magnetic | of | of | | Oxygen | |
| | Minimum Plane | Lower | Field | Crucible | Crystal | Production | Concentration | ROG |
| | [mm] | Coils | [G] | [rpm] | [rpm] | Performance | [atoms/cm³] | [%] |
| Example 1 | 10 mm Downward | 1.00 | 1000 | 0.5 | 10 | Good | 1.45E17 to | 1.7 |
| | from Surface | | | | | | 1.48E17 | |
| Example 2 | 10 mm Downward | 1.00 | 1000 | 1.0 | 10 | Good | 1.73E17 to | 2.6 |
| | from Surface | | | | | | 1.78E17 | |

When conditions in Examples 1 and 2 of the inventive method for producing a silicon single crystal were applied, it was successfully achieved to pull up the single crystal without any dislocation occurring during the straight body step. Regarding crystal quality of the product portion, the oxygen concentration of 2×10¹⁷ atoms/cm³ (ASTM' 79) or less, along with ROG of less than 8% was also achieved. The single crystal having low oxygen concentration and an excellent in-plane distribution of oxygen concentration was successfully pulled up without degrading production performance.

### Examples 3 and 4

Silicon single crystals were produced under the conditions shown below in Examples 3 and 4.

### [Straight Body Step (Product Portion)]

Position of a magnetic field minimum plane: 5 mm upward from a melt surface
Degree of imbalance: 1.00 (Vertically symmetrical excitation)
Intensity of the magnetic field at an intersection of a plane having a same height as a magnetic field minimum plane and an inner wall of a crucible: 800 G (Example 3), 1200 G (Example 4)
Rotational rate of the crucible: 1.00 rpm
Rotational rate of the single crystal: 10 rpm

In Examples 3 and 4, production of a total of two single crystals was performed, fixing a position of a magnetic field minimum plane of a cusp magnetic field, a degree of imbalance, a rotational rate of a crucible, and a rotational rate of the single crystal in a straight body step, while setting intensities of the magnetic field to 800 G (Example 3) and 1200 G (Example 4). Table 2 shows the conditions and results of Examples 3 and 4.

TABLE 2

| | Product | Degree of | | | | | | |
|---|---|---|---|---|---|---|---|---|
| | Portion: | Imbalance | Intensity | Rotational | Rotational | | | |
| | Position of | between | of | Rate | Rate | | | |
| | Magnetic Field | Upper and | Magnetic | of | of | | Oxygen | |
| | Minimum Plane | Lower | Field | Crucible | Crystal | Production | Concentration | ROG |
| | [mm] | Coils | [G] | [rpm] | [rpm] | Performance | [atoms/cm³] | [%] |
| Example 3 | 5 mm Upward | 1.00 | 800 | 1.0 | 10 | Good | 1.60E17 to | 2.5 |
| | from Surface | | | | | | 1.64E17 | |
| Example 4 | 5 mm Upward | 1.00 | 1200 | 1.0 | 10 | Good | 1.73E17 to | 2.6 |
| | from Surface | | | | | | 1.78E17 | |

Even when conditions in Examples 3 and 4 of the inventive method for producing a silicon single crystal were applied, it was successfully achieved to pull up the single crystal without any dislocation occurring during the straight body step. Regarding crystal quality of the product portion, in all cases, the oxygen concentration of 2×10¹⁷ atoms/cm³ (ASTM' 79) or less, along with ROG of less than 8% was also obtained. The single crystal having low oxygen concentration and an excellent in-plane distribution of oxygen concentration was successfully pulled up without degrading production performance.

### Examples 5 and 6

Silicon single crystals were produced under the conditions shown below in Examples 5 and 6.

### [Straight Body Step (Product Portion)]

Position of a magnetic field minimum plane: 5 mm upward from a melt surface
Degree of imbalance: 1.00 (Vertically symmetrical excitation)
Intensity of the magnetic field at an intersection of a plane having a same height as a magnetic field minimum plane and an inner wall of a crucible: 1000 G
Rotational rate of the crucible: 1.00 rpm
Rotational rate of the single crystal: 7 rpm (Example 5), 12 rpm (Example 6)

In Examples 5 and 6, production of a total of two single crystals was performed, fixing a position of a magnetic field minimum plane of a cusp magnetic field, a degree of imbalance, intensity of the magnetic field, and rotational rate of a crucible in a straight body step, while setting rotational rates of the single crystal to 7 rpm (Example 5), and 12 rpm (Example 6). Table 3 shows the conditions and results of Examples 5 and 6.

TABLE 3

| | Product | Degree of | | | | | | |
|---|---|---|---|---|---|---|---|---|
| | Portion: | Imbalance | Intensity | Rotational | Rotational | | | |
| | Position of | between | of | Rate | Rate | | | |
| | Magnetic Field | Upper and | Magnetic | of | of | | Oxygen | |
| | Minimum Plane | Lower | Field | Crucible | Crystal | Production | Concentration | ROG |
| | [mm] | Coils | [G] | [rpm] | [rpm] | Performance | [atoms/cm³] | [%] |
| Example 5 | 5 mm Upward | 1.00 | 1000 | 1.0 | 7 | Good | 1.75E17 to | 2.3 |
| | from Surface | | | | | | 1.79E17 | |
| Example 6 | 5 mm Upward | 1.00 | 1000 | 1.0 | 12 | Good | 1.84E17 to | 2.2 |
| | from Surface | | | | | | 1.88E17 | |

Even when conditions in Examples 5 and 6 of the inventive method for producing a silicon single crystal were applied, it was successfully achieved to pull up the single crystal without any dislocation occurring during the straight body step. Regarding crystal quality of the product portion, in all cases, the oxygen concentration of 2×10¹⁷ atoms/cm³ (ASTM' 79) or less, along with ROG of less than 8% was also obtained. The single crystal having a low oxygen concentration and an excellent in-plane distribution of oxygen concentration was successfully pulled up without degrading production performance.

### Examples 7 and 8

Silicon single crystals were produced under the conditions shown below in Examples 7 and 8.

### [Straight Body Step (Product Portion)]

Position of a magnetic field minimum plane: 10 mm downward from a melt surface
Degree of imbalance: 1.10 (unbalanced excitation)
Intensity of the magnetic field at an intersection of a plane having a same height as a magnetic field minimum plane and an inner wall of a crucible: 1000 G
Rotational rate of the crucible: 0.5 rpm (Example 7), 1.0 rpm (Example 8)
Rotational rate of the single crystal: 10 rpm

In Examples 7 and 8, after changing excitation mode to unbalanced excitation, production of a total of two single crystals was performed, fixing the position of the magnetic field minimum plane, a degree of imbalance, intensity of the magnetic field, and a rotational rate of the single crystal in a straight body step, while setting rotational rates of a crucible to 0.5 rpm (Example 7), and 1.0 rpm (Example 8). Table 4 shows the conditions and results of Examples 7 and 8.

TABLE 4

| | Product | Degree of | | | | | | |
|---|---|---|---|---|---|---|---|---|
| | Portion: | Imbalance | Intensity | Rotational | Rotational | | | |
| | Position of | between | of | Rate | Rate | | | |
| | Magnetic Field | Upper and | Magnetic | of | of | | Oxygen | |
| | Minimum Plane | Lower | Field | Crucible | Crystal | Production | Concentration | ROG |
| | [mm] | Coils | [G] | [rpm] | [rpm] | Performance | [atoms/cm³] | [%] |
| Example 7 | 10 mm Downward | 1.10 | 1000 | 0.5 | 10 | Good | 1.48E17 to | 2.7 |
| | from Surface | | | | | | 1.52E17 | |
| Example 8 | 10 mm Downward | 1.10 | 1000 | 1.0 | 10 | Good | 1.74E17 to | 3.5 |
| | from Surface | | | | | | 1.80E17 | |

Even when conditions in Examples 7 and 8 of the inventive method for producing a silicon single crystal were applied, it was successfully achieved to pull up the single crystal without any dislocation occurring during the straight body step. Regarding crystal quality of the product portion, in all cases, the oxygen concentration of 2×10¹⁷ atoms/cm³ (ASTM' 79) or less, along with ROG of less than 8% was also obtained. The single crystal having low oxygen concentration and an excellent in-plane distribution of oxygen concentration was successfully pulled up without degrading production performance.

### Examples 9 and 10

Silicon single crystals were produced under the conditions shown below in Examples 9 and 10.

### [Straight Body Step (Product Portion)]

Position of magnetic field minimum plane: 10 mm downward from a melt surface
Degree of imbalance: 1.10 (unbalanced excitation)
Intensity of the magnetic field at an intersection of a plane having a same height as a magnetic field minimum plane and an inner wall of a crucible: 800 G (Example 9), 1200 G (Example 10)
Rotational rate of the crucible: 1.0 rpm
Rotational rate of the single crystal: 10 rpm

In Examples 9 and 10, after changing excitation mode to unbalanced excitation, production of a total of two single crystals was performed, fixing a position of a magnetic field minimum plane, a degree of imbalance, a rotational rate of a crucible, and a rotational rate of the single crystal in a straight body step, while setting intensities of the magnetic field to 800 G (Example 9), and 1200 G (Example 10). Table 5 shows the conditions and results of Examples 9 and 10.

TABLE 5

| | Product | Degree of | | | | | | |
|---|---|---|---|---|---|---|---|---|
| | Portion: | Imbalance | Intensity | Rotational | Rotational | | | |
| | Position of | between | of | Rate | Rate | | | |
| | Magnetic Field | Upper and | Magnetic | of | of | | Oxygen | |
| | Minimum Plane | Lower | Field | Crucible | Crystal | Production | Concentration | ROG |
| | [mm] | Coils | [G] | [rpm] | [rpm] | Performance | [atoms/cm³] | [%] |
| Example 9 | 10 mm Downward | 1.10 | 800 | 1.0 | 10 | Good | 1.55E17 to | 4.5 |
| | from Surface | | | | | | 1.62E17 | |
| Example 10 | 10 mm Downward | 1.10 | 1200 | 1.0 | 10 | Good | 1.65E17 to | 3.6 |
| | from Surface | | | | | | 1.71E17 | |

Even when conditions in Examples 9 and 10 of the inventive method for producing a silicon single crystal were applied, it was successfully achieved to pull up the single crystal without any dislocation occurring during the straight body step. Regarding crystal quality of the product portion, in all cases, the oxygen concentration of 2×10¹⁷ atoms/cm³ (ASTM' 79) or less, along with ROG of less than 8% was also obtained. The single crystal having low oxygen concentration and an excellent in-plane distribution of oxygen concentration was successfully pulled up without degrading production performance.

### Examples 11, 12

Silicon single crystals were produced under the conditions shown below in Examples 11 and 12.

### [Straight Body Step (Product Portion)]

Position of magnetic field minimum plane: 10 mm downward from a melt surface
Degree of imbalance: 1.10 (unbalanced excitation)
Intensity of the magnetic field at an intersection of a plane having a same height as a magnetic field minimum plane and an inner wall of a crucible: 1000 G
Rotational rate of the crucible: 1.0 rpm
Rotational rate of the single crystal: 7 rpm (Example 11), 12 rpm (Example 12)

In Examples 11 and 12, after changing excitation mode to unbalanced excitation, production of a total of two single crystals was performed, fixing a position of a magnetic field minimum plane, a degree of imbalance, an intensity of the magnetic field, and a rotational rate of a crucible in a straight body step, while setting rotational rates of single crystals to 7 rpm (Example 11), 12 rpm (Example 12). Table 6 shows the conditions and results of Examples 11 and 12.

TABLE 6

| | Product | Degree of | | | | | | |
|---|---|---|---|---|---|---|---|---|
| | Portion: | Imbalance | Intensity | Rotational | Rotational | | | |
| | Position of | between | of | Rate | Rate | | | |
| | Magnetic Field | Upper and | Magnetic | of | of | | Oxygen | |
| | Minimum Plane | Lower | Field | Crucible | Crystal | Production | Concentration | ROG |
| | [mm] | Coils | [G] | [rpm] | [rpm] | Performance | [atoms/cm³] | [%] |
| Example 11 | 10 mm Downward | 1.10 | 1000 | 1.0 | 7 | Good | 1.70E17 to | 4.1 |
| | from Surface | | | | | | 1.77E17 | |
| Example 12 | 10 mm Downward | 1.10 | 1000 | 1.0 | 12 | Good | 1.72E17 to | 2.9 |
| | from Surface | | | | | | 1.77E17 | |

Even when conditions in Examples 11 and 12 of the inventive method for producing a silicon single crystal were applied, it was successfully achieved to pull up the single crystal without any dislocation occurring during the straight body step. Regarding crystal quality of the product portion, in all cases, the oxygen concentration was 2×10¹⁷ atoms/cm³ (ASTM' 79) or less, along with ROG of less than 8% was also obtained. The single crystal having a low oxygen concentration and an excellent in-plane distribution of oxygen concentration was successfully pulled up without degrading production performance.

### Comparative Example 1

In Comparative Example 1, a rotational rate of a crucible in a straight body step (product portion) was set to 1.5 rpm, and a single crystal was produced under the same conditions as Example 1 for all other conditions. Table 7 shows the conditions and results of Comparative Example 1.

TABLE 7

| | Product | | | | | | | |
|---|---|---|---|---|---|---|---|---|
| | Portion: | Degree of | | | | | | |
| | Position of | Imbalance | Intensity | Rotational | Rotational | | | |
| | Magnetic | between | of | Rate | Rate | | | |
| | Field | Upper and | Magnetic | of | of | | Oxygen | |
| | Minimum | Lower | Field | Crucible | Crystal | Production | Concentration | ROG |
| | Plane [mm] | Coils | [G] | [rpm] | [rpm] | Performance | [atoms/cm³] | [%] |
| Comparative | 10 mm | 1.00 | 1000 | 1.5 | 10 | Good | 2.36E17 to | 10.2 |
| Example 1 | Downward | | | | | | 2.60E17 | |
| | from Surface | | | | | | | |

When conditions in Comparative Example 1 were applied, it was successfully achieved to pull up the single crystal without any dislocation occurring during the straight body step. However, an oxygen concentration thereof was higher than 2×10¹⁷ atoms/cm³ and ROG was higher than 8%.

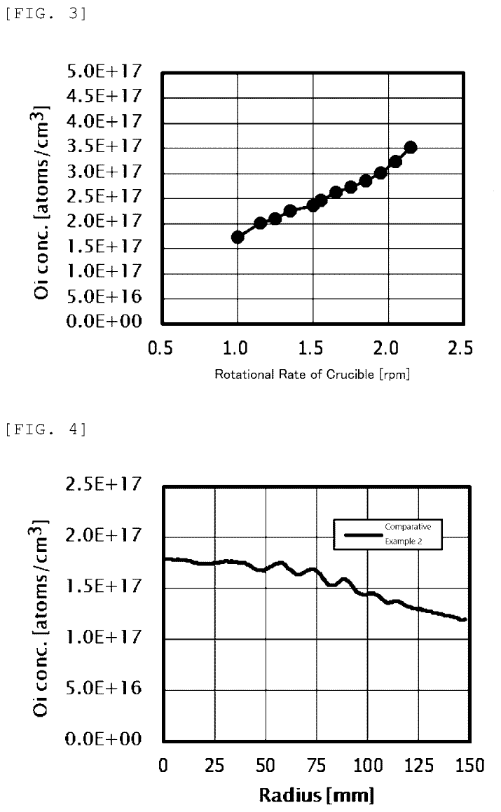

For confirmation, a single crystal was produced with a rotational rate of a crucible being varied in a range of 1.0 to 2.2 rpm, while other conditions were the same conditions in Comparative Example 1, resulting in a monotonous increase of the oxygen concentration with an increase in the rotational rate of the crucible as shown in FIG. 3. Consequently, it is found that in order to obtain a single crystal having the low oxygen concentration and an excellent in-plane distribution of an oxygen concentration that satisfies the required quality for a power device and an RF device, it is necessary to set the rotation rate of the crucible to 1.0 rpm or less as in the inventive method for producing a silicon single crystal.

### Comparative Examples 2 and 3

In Comparative Examples 2 and 3, a crystal rotational rate in a straight body step (product portion) was set to 6 rpm (Comparative Example 2) or 13 rpm (Comparative Example 3), and single crystals were pulled up under the same conditions as Example 1 for other conditions. Table 8 shows the conditions and results of Comparative Examples 2 and 3, FIG. 4 shows the in-plane distribution of the oxygen concentration at 100 cm of a straight body obtained in Comparative Example 2.

TABLE 8

| | Product | | | | | | | |
|---|---|---|---|---|---|---|---|---|
| | Portion: | Degree of | | | | | | |
| | Position of | Imbalance | Intensity | Rotational | Rotational | | | |
| | Magnetic | between | of | Rate | Rate | | | |
| | Field | Upper and | Magnetic | of | of | | Oxygen | |
| | Minimum | Lower | Field | Crucible | Crystal | Production | Concentration | ROG |
| | Plane [mm] | Coils | [G] | [rpm] | [rpm] | Performance | [atoms/cm³] | [%] |
| Comparative | 10 mm | 1.00 | 1000 | 0.5 | 6 | Good | 1.20E17 to | 33.4 |
| Example 2 | Downward | | | | | | 1.78E17 | |
| | from Surface | | | | | | | |
| Comparative | 10 mm | 1.00 | 1000 | 0.5 | 13 | poor | | |
| Example 3 | Downward | | | | | | | |
| | from Surface | | | | | | | |

When the crystal rotational rate in the straight body step (product portion) was set to 6 rpm, it was successfully achieved to pull up the single crystals without any dislocation occurring during the straight body step. However, the in-plane distribution of oxygen was degraded and then ROG of 8% or less was unable to be satisfied. Moreover, when the crystal rotational rate in the straight body step (product portion) was set to 13 rpm, crystal deformation was intensified during pulling up, making an operation difficult to continue. Consequently, it is found that in order to obtain a single crystal having a low oxygen concentration and an excellent in-plane distribution of an oxygen concentration that satisfies the required quality for a power device and an RF device, it is necessary to set the crystal rotation rate to 7 rpm or more and 12 rpm or less in the straight body step (product portion) as in the inventive method for producing a silicon single crystal.

### Comparative Examples 4 to 7

In Comparative Examples 4 to 7, intensity of the magnetic field in a straight body step (product portion) was set to 700 G (Comparative Example 4) or 1300 G (Comparative Example 5), a position of a magnetic field minimum plane in the straight body step was set to 10 mm upward from a melt surface (Comparative Example 6) or 15 mm downward from the melt surface (Comparative Example 7) by unbalanced excitation, and single crystals were pulled up under the same conditions as Example 2 for other conditions. Table 9 shows the conditions and results of Comparative Examples 4 to 7.

TABLE 9

| | Product | | | | | | | |
|---|---|---|---|---|---|---|---|---|
| | Portion: | Degree of | | | | | | |
| | Position of | Imbalance | Intensity | Rotational | Rotational | | | |
| | Magnetic | between | of | Rate | Rate | | | |
| | Field | Upper and | Magnetic | of | of | | Oxygen | |
| | Minimum | Lower | Field | Crucible | Crystal | Production | Concentration | ROG |
| | Plane [mm] | Coils | [G] | [rpm] | [rpm] | Performance | [atoms/cm³] | [%] |
| Comparative | 10 mm | 1.00 | 700 | 1.0 | 10 | poor | | |
| Example 4 | Downward | | | | | | | |
| | from Surface | | | | | | | |
| Comparative | 10 mm | 1.00 | 1300 | 1.0 | 10 | Good | 2.10E17 to | 3.8 |
| Example 5 | Downward | | | | | | 2.18E17 | |
| | from Surface | | | | | | | |
| Comparative | 10 mm Upward | 1.00 | 1000 | 1.0 | 10 | Good | 2.15E17 to | 4.2 |
| Example 6 | from Surface | | | | | | 2.24E17 | |
| Comparative | 15 mm | 1.00 | 1000 | 1.0 | 10 | Good | 2.30E17 to | 5.2 |
| Example 7 | Downward | | | | | | 2.42E17 | |
| | from Surface | | | | | | | |

When the intensity of the magnetic field in the straight body step (product portion) was set to 700 G, crystal deformation was intensified during pulling up, making an operation difficult to continue. On the other hand, when the intensity of the magnetic field in the straight body step (product portion) was set to 1300 G, an oxygen concentration rose higher than 2×10¹⁷ atoms/cm³. Moreover, when the position of the magnetic field minimum plane in the straight body step (product portion) was set to 10 mm upward from a melt surface, or even when 15 mm downward from the melt surface, the oxygen concentration rose higher than 2×10¹⁷ atoms/cm³. Consequently, it is found that in order to obtain a single crystal having a low oxygen concentration and an excellent in-plane distribution of an oxygen concentration that satisfies the required quality for a power device and an RF device, it is necessary to set an absolute value of intensity of the magnetic field to 800 G or more and 1200 G or less, and a position of a magnetic field minimum plane in a range of 10 mm downward to 5 mm upward from a raw-material melt surface in the straight body step (product portion) as in the inventive method for producing a silicon single crystal.

### Comparative Example 8

In Comparative Example 8, a rotational rate of a crucible in a straight body step (product portion) was set to 1.5 rpm, and a single crystal was produced under the same conditions (unbalanced excitation) as Example 7 for other conditions. Table 10 shows the conditions and results of Comparative Example 8.

TABLE 10

| | Product | | | | | | | |
|---|---|---|---|---|---|---|---|---|
| | Portion: | Degree of | | | | | | |
| | Position of | Imbalance | Intensity | Rotational | | | | |
| | Magnetic | between | of | Rate | Rotational | | | |
| | Field | Upper and | Magnetic | of | Rate of | | Oxygen | |
| | Minimum | Lower | Field | Crucible | Crystal | Production | Concentration | ROG |
| | Plane [mm] | Coils | [G] | [rpm] | [rpm] | Performance | [atoms/cm³] | [%] |
| Comparative | 10 mm | 1.10 | 1000 | 1.5 | 10 | Good | 2.30E17 to | 12.0 |
| Example 8 | Downward | | | | | | 2.58E17 | |
| | from Surface | | | | | | | |

When the conditions of Comparative Example 8 were applied, it was successfully achieved to pull up the single crystal without any dislocation occurring during the straight body step, but an oxygen concentration thereof rose higher than 2×10¹⁷ atoms/cm³ and ROG was higher than 8%. Consequently, even when an excitation mode is made to be an unbalanced excitation, it is found that in order to obtain a single crystal having a low oxygen concentration and an excellent in-plane distribution of an oxygen concentration that satisfies the required quality for a power device and an RF device, it is necessary to set the rotation rate of the crucible to 1.0 rpm or less as in the inventive method for producing a silicon single crystal.

### Comparative Examples 9 and 10

In Comparative Examples 9 and 10, a crystal rotational rate in a straight body step (product portion) was set to 6 rpm (Comparative Example 9) or 13 rpm (Comparative Example 10), and single crystals were pulled up under the same conditions as Example 7 for other conditions. Table 11 shows the conditions and results of Comparative Examples 9 and 10.

TABLE 11

| | | | | | | | |
|---|---|---|---|---|---|---|---|
| Product | | | | | | | |
| Portion: | Degree of | | | | | | |
| Position of | Imbalance | Intensity | Rotational | Rotational | | | |
| Magnetic | between | of | Rate | Rate | | | |
| Field | Upper and | Magnetic | of | of | | Oxygen | |
| Minimum | Lower | Field | Crucible | Crystal | Production | Concentration | ROG |
| Plane [mm] | Coils | [G] | [rpm] | [rpm] | Performance | [atoms/cm³] | [%] |

| | | | | | | |
|---|---|---|---|---|---|---|
| Comparative | 10 mm | 1.10 | 1000 | 0.5 | 6 | poor |
| Example 9 | Downward | | | | | |
| | from Surface | | | | | |
| Comparative | 10 mm | 1.10 | 1000 | 0.5 | 13 | poor |
| Example 10 | Downward | | | | | |
| | from Surface | | | | | |

When the crystal rotational rate in a straight body step (product portion) was set to 6 rpm, a crank was generated in the straight body step, making an operation difficult to continue. Moreover, when the crystal rotational rate in a straight body step (product portion) was set to 13 rpm, crystal deformation was intensified during pulling up, making the operation difficult to continue. Consequently, even when an excitation mode is made to be an unbalanced excitation, it is found that in order to obtain a single crystal having a low oxygen concentration and an excellent in-plane distribution of an oxygen concentration that satisfies the required quality for a power device and an RF device, it is necessary to set the crystal rotation rate in the straight body step (product portion) to 7 rpm or more and 12 rpm or less as in the inventive method for producing a silicon single crystal.

### Comparative Examples 11 to 14

In Comparative Examples 11 to 14, an intensity of the magnetic field in a straight body step (product portion) was set to 700 G (Comparative Example 11) or 1300 G (Comparative Example 12), a position of a magnetic field minimum plane in a straight body step (product portion) was set to 10 mm upward from a melt surface (Comparative Example 13) or 15 mm downward from the melt surface (Comparative Example 14), and a single crystal was pulled up under the same conditions as Example 8 for other conditions. Table 12 shows the conditions and results of Comparative Examples 11 to 14.

TABLE 12

| | Product | | | | | | | |
|---|---|---|---|---|---|---|---|---|
| | Portion: | Degree of | | | | | | |
| | Position of | Imbalance | Intensity | Rotational | Rotational | | | |
| | Magnetic | between | of | Rate | Rate | | | |
| | Field | Upper and | Magnetic | of | of | | Oxygen | |
| | Minimum | Lower | Field | Crucible | Crystal | Production | Concentration | ROG |
| | Plane [mm] | Coils | [G] | [rpm] | [rpm] | Performance | [atoms/cm³] | [%] |
| Comparative | 10 mm | 1.10 | 700 | 1.0 | 10 | poor | | |
| Example 11 | Downward | | | | | | | |
| | from Surface | | | | | | | |
| Comparative | 10 mm | 1.10 | 1300 | 1.0 | 10 | Good | 2.12E17 to | 2.4 |
| Example 12 | Downward | | | | | | 2.17E17 | |
| | from Surface | | | | | | | |
| Comparative | 10 mm Upward | 1.10 | 1000 | 1.0 | 10 | Good | 2.14E17 to | 5.1 |
| Example 13 | from Surface | | | | | | 2.25E17 | |
| Comparative | 15 mm | 1.10 | 1000 | 1.0 | 10 | Good | 2.28E17 to | 5.3 |
| Example 14 | Downward | | | | | | 2.40E17 | |
| | from Surface | | | | | | | |

When the intensity of the magnetic field in the straight body step (product portion) was set to 700 G, crystal deformation was intensified during pulling up, making an operation difficult to continue. On the other hand, when the intensity of the magnetic field in the straight body step (product portion) was set to 1300 G, an oxygen concentration rose higher than 2×10¹⁷ atoms/cm³. Moreover, when the position of the magnetic field minimum plane in the straight body step (product portion) was set to 10 mm upward from a melt surface, or even when 15 mm downward from the melt surface, the oxygen concentration rose higher than 2×10¹⁷ atoms/cm³. Consequently, even when an excitation mode is made to be an unbalanced excitation, it is found that in order to obtain a single crystal having a low oxygen concentration and an excellent in-plane distribution of an oxygen concentration that satisfies the required quality for a power device and an RF device, it is necessary to set an absolute value of the intensity of the magnetic field to 800 G or more and 1200 G or less, and the position of the magnetic field minimum plane was set in a range of 10 mm downward to 5 mm upward from a raw-material melt surface in the straight body step (product portion) as in the inventive method for producing a silicon single crystal.

As described above, according to Examples of the present invention, problems, such as an increase in the oxygen concentration and a deterioration in the in-plane distribution of the oxygen concentration when the rotation rate of the crucible was increased, were eliminated. This enabled the efficient production of a single crystal having a low oxygen concentration and excellent in-plane distribution of the oxygen concentration, satisfying the required quality for the power device and the RF device.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A method for producing a silicon single crystal by a CZ method using a cusp magnetic field formed by an upper coil and a lower coil provided in a pulling furnace, wherein
the silicon single crystal is pulled up in a straight-body step by setting a rotational rate of the silicon single crystal to 7 rpm or more and 12 rpm or less, a rotational rate of a quartz crucible to 1.0 rpm or less, a position of a magnetic field minimum plane of the cusp magnetic field in a range of 10 mm downward to 5 mm upward from a raw-material melt surface, and an intensity of the magnetic field of the cusp magnetic field at an intersection of a plane having a same height as the magnetic field minimum plane and an inner wall of the quartz crucible from 800 to 1200 G.

2. The method for producing the silicon single crystal according to claim 1, wherein
the silicon single crystal is produced in which an oxygen concentration based on ASTM' 79 is 2×10¹⁷ atoms/cm³ or less, and an ROG in a crystal cross-section at right angles to a growth direction of the silicon single crystal is 8% or less.
